(19) United States
(12) Patent Application Publication
(10) Pub. No.: US 2015/0068556 A1
(43) Pub. Date: Mar. 12, 2015

(54) DEVICE FOR THE REMOVAL OF A COVERING FROM A SUBSTRATE AND A METHOD PERTAINING THERETO

(71) Applicant: SOLAR-SEMI GMBH, Radolfzell (DE)

(72) Inventor: Pirmin Muffler, Orsingen-Nenzingen (DE)

(21) Appl. No.: 14/389,038

(22) PCT Filed: Mar. 26, 2013
(86) PCT No.: PCT/EP2013/056333

§ 371 Date: Sep. 29, 2014

(30) Foreign Application Priority Data
Mar. 29, 2012 (DE) 10 2012 102 740.4
Apr. 17, 2012 (DE) 10 2012 103 330.7

(51) Int. Cl. H01L 21/67

(52) U.S. Cl. CPC H01L 21/67023; H01L 21/67051
USPC 134/18; 134/198; 134/102.2; 134/151; 134/113; 134/153; 134/34; 134/36

(57) ABSTRACT

A device (1) for removing a coating, particularly a photoresist, from a substrate (10) in at least one area of the substrate (10), comprises a nozzle (11) suitable for applying a jet of a solution medium to the substrate.

### BACKGROUND OF THE INVENTION

The invention pertains to a method and device intended for the removal of a covering from a substrate.

Some substrates, as for example wafers or boards, are given a layer of covering according to various uses or steps during processing. In most cases, this covering process is carried out over the entire surface of said substrate. In certain embodiments, a margin of said substrate needs to be free of covering. The disadvantage to this circumstance lies in the fact, that it is very cumbersome and costly to apply a covering to a substrate only in part, and, at the same, time very evenly.

It is an object of the invention to provide a device, as well a method, by which it is possible to remove the covering from an area of the substrate in a precise manner, without causing damage to said substrate.

### SUMMARY OF THE INVENTION

The objective is achieved in accordance with a first embodiment of the present invention by providing a device intended for the removal of a layer, in particular of photosensitive paint, from a substrate in at least an area of said substrate which comprises a nozzle. Preferably, the nozzle is suitable to the purpose of applying a jet of solution medium.

In a typical embodiment, the covering layer comprises photosensitive paint. The covering layer may still be liquid or also already dried. Preferably, the applied solution medium is chosen according to the covering layer waiting to be removed.

Especially preferred is a design by which said covering layer, in a margin of itself, is to be removed by one jet. From the use of the above said nozzle results the advantage that a certain margin of the surface area to be removed can be defined by establishing how near, or how far, from an edge of said substrate the nozzle is to be guided. Preferably to be removed is, from an area, stretching at a distance of 1 mm to 30 mm, on an edge, of said substrate. Furthermore advantageous is the fact that, by suitable choice of solution agent and pressure of said jet, the covering layer may be removed entirely.

In typical embodiments, the nozzle is suited to the process of applying the jet of solution medium in such a manner that it is guided within a jet of pressurized air. This results in the advantage that the jet of solution medium is very stable. This circumstance makes possible a precise removal of an area of the covering layer covering the substrate.

In typical embodiments, the device comprises a gas suction facility. This offers the advantage that the solution medium bouncing back from the substrate is not emitted, but to the contrary is led out by means of suction and, in certain circumstances, may be reused. A further advantage of the suction device also lies in the fact that the covering layer upon removal from the substrate can be vacuumed away and is not emitted into the environment.

In typical embodiments, the suction facility comprises a separating device. This circumstance results in the advantage that from the vacuumed medium, the removed covering layer and the solution medium may be separated from the pressurized air. Preferably, a condensator is used as a separating device. This circumstance results in the advantage that the process of separating the pressurized air and the matter contained therein can be carried out in a simple manner.

In typical embodiments the suction facility or the separating device comprises a a condensator. Especially preferable in the use as a condensator is a bouncing wall. Preferably, the bouncing wall is suitable for condensating, at least partially, the vacuumed medium.

It is especially preferable to have the vacuumed medium guided onto the bouncing wall and having it stopped suddenly at said bouncing wall. Due to this configuration, the medium is condensed. Preferably, the medium condensing at the bouncing wall can be guided into the recycling facility via a discharge element. This circumstance results in the advantage that the solution medium may be reused.

In typical embodiments, the device comprises a receiving element. Preferably, the receiving element is suited to holding, positioning, guiding and/or the adjusting of said substrate in relation to the nozzle and/or the jet of solution medium. This circumstance results in the advantage that a relational movement occurring between the jet of solution medium and the substrate in a simple manner is made possible. Furthermore, it is advantageous that the complicated structure comprising nozzle and gas suction facility need not be moved.

Preferably, the receiving element comprises a facility intended for stretching flat the substrate upon the underlying. Preferably the device intended for flat-stretching comprises at least one suctioning nozzle. Preferably, the device comprises several or a plurality of suctioning nozzles. Especially to be preferred is a configuration by which suctioning nozzles are positioned in such a manner that they take effect upon the marginal areas of the substrate. Thus results the advantage that the substrate, especially in those areas in which the covering layer is to be removed, is correctly positioned and the substrate is prevented from taking effect. This design is especially advantageous, since, in the case of a born substrate, damage to the substrate and/or an insufficient removal of the covering layer might otherwise occur.

In typical embodiments, the device comprises a guide unit. The viewing unit is suited to the intent of directionally guiding the substrate in a correct manner in relation to the nozzle, respectively, the jet of solution medium. Preferably, the viewing or adjusting unit establishes and/or adjusts the position of the substrate based on a measurement at several points. Preferably measurement is taken at two points.

In typical embodiments the guide unit comprises a sensor which is set in motion for said measurements. Alternatively, the guide unit comprises two sensors, respectively, a plurality of sensors. In this case it would be preferable that no motion need occur.

In typical embodiments the device comprises a recognition facility suited to recognizing a contour of a substrate. Preferably, the facility in question is formed by a camera or a distance measuring sensor. Thus results the advantage that the contour of the substrate can be recognized. This is an especially advantageous circumstance, since, in this case, substrates with an uneven contour can also have their coat of paint removed. A further advantage lies in the circumstance that the position and the shape line of the contour are also recognizable.

The problem which arises when removing a covering layer in a marginal area, especially while removing a coat of paint from round substrates shaped like circular plates, is that the latter generally possess at their circumference an unevenness, such as a so-called flat, i.e. a missing segment of the circular arch or a notch, i.e. something resembling a cut-out. If and when a round substrate, in order to have a covering layer removed from a marginal area, is simply rotated beneath a jet of solution medium, respectively, a nozzle, the problem arises that at the flat, or at the notch, the contours of which simply do not lie upon the circular circumference, the covering layer cannot be removed. This problem becomes especially urgent because, due to the rotational movement of the substrate during the process of applying the covering layer, a pad is formed. Said pad constitutes an impediment to the following processing steps.

In typical embodiments the device comprises a power drive, which is suitable to drive in a rotating manner the receiving element. Thus the power drive is also suited to rotating a substrate lying upon the receiving element. Preferably the substrate is rotated within a plane that for all important purposes extends vertically to a direction of the jet of the solution medium. Thus results the advantage that all is needed in order to remove the covering layer along the circular contour of the substrate, is to rotate the receiving element along with the substrate.

It is also advantageous that the substrate, by rotating the receiving element, can, in a simple manner be guided along the recognition facility. The recognition facility intended for recognizing a contour, in this instance, is preferably positioned above a marginal area of the substrate in such a manner that the device, in case the substrate is rotated, can recognize the shape line of the contour.

In typical embodiments the device comprises a linear force drive and/or a linear guide facility, suited to the task of sliding the receiving element linearly in relation to the nozzle.

Preferably, the linear force drive and/or the linear guide facility are suited to the task of moving the receiving element, preferably together with the substrate, under or in relation to the recognition facility, in such a manner that the latter can recognize the entire contour of the substrate when the substrate is rotated beneath the recognition facility.

Preferably, the linear force drive and/or the linear guide are suited to the task of sliding the receiving element together with the rotational power drive between the recognition facility and the nozzle.

Even more preferable is a configuration in which the linear force drive and/or the linear guide, are also suited to the task of positioning the receiving element and, consequently, also the substrate under the nozzle, respectively, the jet of solution medium, in such a manner that, by rotating the receiving element, a covering layer in the marginal areas of the substrate can be removed.

It is especially preferable for both drives, i.e. the rotational power drive and the linear force drive, to be operated simultaneously. This results in the advantage that the receiving element and, consequently, also the substrate are not moved in a rotational or a linear manner only. By overlaying both directions of movement, the receiving element and, consequently, also the substrate can be moved along all conceivable free variations of shape and form. This is an advantageous circumstance, because the substrate, in this case, can be moved underneath the nozzle, respectively, the jet of solution medium in such a manner that a cover covering layer can be removed along the flat and the notch. This circumstance results in the advantage that in one process step a covering layer in a marginal area of the substrate can be removed entirely, even if said substrate possesses uneven sections, such as a flat or a notch.

Special claim is made for protection of a method for the removal of a covering layer, in particular photosensitive paint, from a substrate in at least one area of the substrate, in which instance the substrate is directionally guided, prior to then applying a solution medium to the substrate.

In typical embodiments, and in order to directionally guide it, the substrate is stretched flat and then the substrate and/or the nozzle are positioned at a distance to the center point of the nozzle, depending on a chosen width of the area in which the covering layer is to be removed. This circumstance results in the advantage that, with one device, a variety of different areas of covering layer on the substrate can be removed in a simple manner.

In typical embodiments, and in order to apply a solution agent to the substrate, the jet of solution medium is guided within a jet of pressurized air. Additionally, in this instance, a relative movement between the substrate and the jet of solution medium is performed. This results in the advantage that, in a very simple manner, a removal of the covering layer is possible.

In typical embodiments, a method for the removal of a covering layer, in particular of photosensitive paint, from an essentially circular substrate, in at least an area of the substrate, comprises the following step:
The recognition of a contour of a substrate. It is preferable in this instance to have the shape of the uneven form, such as a flat or a notch, recognized. It is especially preferable to have the position of the unevenness recognized. Preferably, the substrate is positioned in relation to the jet of solution medium, all depending on a chosen width of the area from which the covering layer is to be removed. It is especially preferable to have the substrate slid, depending on the recognized contour, in relation to the jet of solution medium, in such a manner that the covering layer in marginal area of the recognized contour is removed. This results in the advantage that at the edges of the substrate, which do not lie upon the round circumference, a removal of the covering layer is possible as well. This is especially important, since a pad generally forms at the edge of the substrate, consisting of the substrate constituting the covering layer, which pad impedes further processing.

Preferably, the substrate, to this end, is rotated beneath the jet of solution medium and is guided—at the positions of uneven segments, via an additional linear movement, which movement is overlaid with the rotational movement—along the contour of the unevenness through the jet of solution medium.

### BRIEF DESCRIPTION OF THE DRAWINGS

In the following, the invention is described in more detail, based upon the appended drawing, the latter showing in its figures:

FIG. 1 shows a schematic illustration of a view in perspective of a device, according to the invention, intended for the removal of a covering layer from a substrate;

FIG. 2 shows a schematic illustration of a lateral view of a device according to the invention, as in FIG. 1, with a substrate;

FIG. 3 shows a schematic illustration of a sectional view of a suction facility belonging to the device according to the invention, intended for the removal of a covering layer, based on FIG. 1;

FIG. 4, a schematic illustration of a side view of a further embodiment of a device in accordance with the invention, especially for the removal of a covering layer in a marginal area in connection with a round substrate;

FIG. 5, a schematic illustration of a top view of the device, in particular for the removal of a covering layer in a marginal area in connection with a round substrate, according to FIG. 4;

FIG. 6 shows a schematic illustration of a circular wafer with a flat;

FIG. 7 shows a schematic illustration of a circular wafer with a notch;

### DETAILED DESCRIPTION

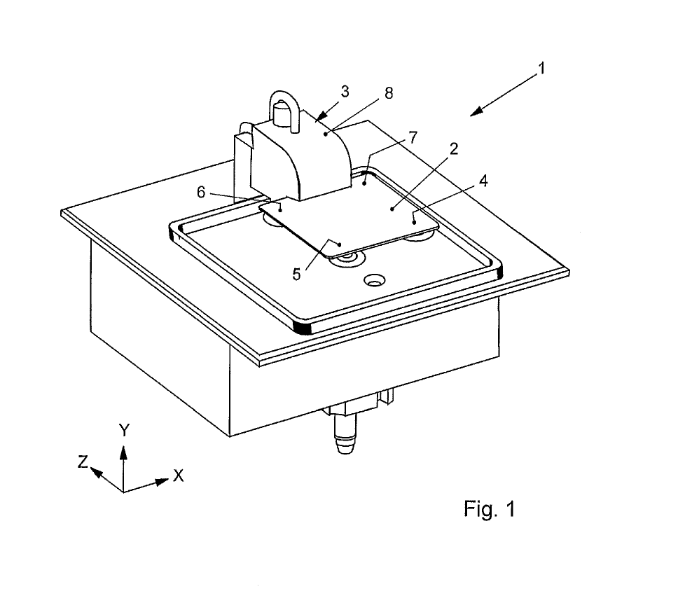

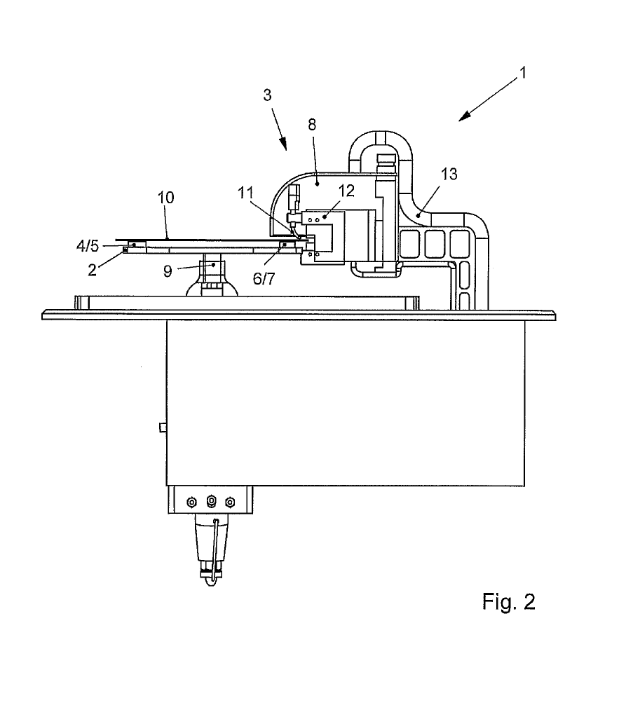

FIGS. 1 and 2 show a device 1 according to the invention intended for the removal of a covering layer, especially of photosensitive paint, from a substrate 10, in at least an area of substrate 10.

The device 1 comprises a receiving element 2 and a removal facility 3.

Examples for possible substrates are: round wafers, rectangular wafers, square wafers, thin layered plates, computer boards and the like.

In the embodiment presented herein, receiving element 2 is formed as a square plate. Receiving element 2 can be slid in relation to the removal facility 3. Preferably, the receiving element comprises an adjusting facility 9. Preferably, adjusting facility 9 is suited to the task of sliding receiving element 2 in a plane X-Z. Preferably, adjusting element 9 is suited to the task of sliding receiving element in a direction Y. This configuration is especially advantageous, if, for example, a distance between removal facility 3 and receiving element 2 is to be altered.

In embodiments not shown here, the removal facility comprises an adjusting facility suited to the task of sliding the adjusting facility in a plane X-Z and/or a direction Y.

In addition, receiving element 3 comprises a plurality of suction nozzles 4, 5, 6 and 7. The suction nozzles 4, 5, 6, and 7 are positioned, essentially, in an area of the corners belonging to receiving element 2 Suction nozzles 4, 5, 6 and 7 serve the function of suctioning substrate 10, which is laid onto receiving element 2, and to stretch said substrate flat. The aim of this process step is to prevent the substrate from lying on the receiving element in a domed fashion. To this end, suction nozzles 4, 5, 6 and 7 are connected to a source of vacuum not illustrated herein.

Removal facility 3 has the task of applying a solution medium [solution medium?] to substrate 10, the latter lying upon receiving element 2, in order to remove a covering layer of substrate 10 in at least an area of substrate 10. Preferably, photosensitive paint is to be removed in a marginal area of substrate 10. As a solution medium, a suitable solution agent can be used, or else small particles that have an abrasive effect.

Additionally, removal facility 3 has the task of suctioning off the solution medium and/or the covering layer removed from substrate 10. To this end, removal facility 3 comprises a cap 8. Cap 8 serves as a protecting facility. Preferably, cap 8 protects the inner works of removal facility 3. In addition, cap 8 serves as a suction cap.

Device 1, especially removal facility 3, comprises a nozzle 11. Nozzle 11 is suited to the task of applying a solution medium. Preferably, nozzle 11 is suited to the task of applying the solution medium as a jet. It is especially to be preferred for nozzle 11 to be suited to the task of guiding the jet of solution medium with pressurized air. To this end, nozzle 11 is preferably connected to a source of pressurized air. Special preference is according to a configuration in which nozzle 11 possesses to application pipes, which extend within each other. Preferably, the jet of solution medium is applied from within the inner pipe. It is especially preferable to have the jet of pressurized air applied from the outer pipe. Said connected to a pump not illustrated herein and a tank of solution medium not illustrated herein. Preferably, the pump is suited to the task of applying the solution medium under pressure.

Additionally, device 1, in particular removal facility 3, comprises a suctioning facility 12. Suctioning facility 12, via a lead pipe 13, is connected to a source of vacuum not illustrated herein.

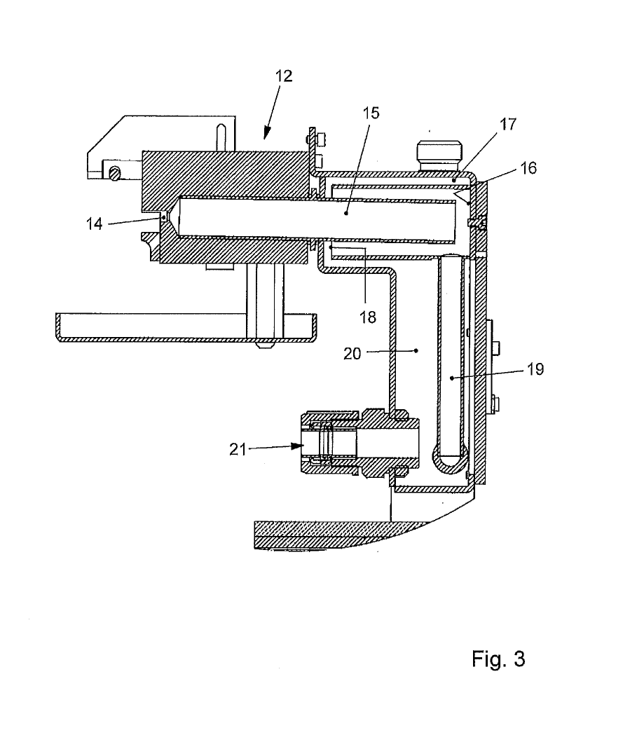

FIG. 3 shows an enlarged sectional illustration of suctioning facility 12. Suctioning facility 12 comprises a suction opening 14. Adjacent to suction opening 14 lies a canal 15. Canal 15 leads to a condensating chamber 17. Condensating chamber 17 comprises a bouncing wall 16. Condensating chamber 17 possesses an open side 18. Open side 18 is positioned opposite to bouncing wall 16.

Adjacent to condensating chamber 17, there is a discharge 19. Discharge 19 is positioned in the vicinity of bouncing wall 16. Open side 18 leads to a chamber 20. Chamber 20 possesses a valve 21.

The invention presented herein functions in the following manner:

Substrate 10, as shown in FIG. 2, is laid upon receiving element 2, respectively, suctioning nozzles 4, 5, 6 and 7. Suctioning nozzles 4, 5, 6 and 7 suction the substrate in such a manner that it is stretched flat and is not domed.

Subsequently, receiving element 2, along with substrate 10, is positioned directionally in relation to nozzle 11, respectively, removal facility 3. To this end device 1 possesses a positioning unit not illustrated herein. Preferably, the positioning unit is suited to the task of establishing, via a double point detecting process, whether the substrate lies in a correct and straight position.

If substrate 10 lies in a correct position in relation to nozzle 11, nozzle 11 is positioned at an edge of substrate 10. Depending on the width of the area from which the covering layer is to be removed, the center of nozzle 11 is positioned in relation to substrate 10.

Subsequently, a jet of solution medium is emitted from nozzle 11, which jet is guided within a jet of pressurized air.

Receiving element 2, along with substrate 10, is moved underneath nozzle 11. For this reason, it is so important to directionally position and stretch flat the substrate in the correct manner. If the substrate at this point in the process were to lie in a slanting manner or if it were domed, the covering layer would not be removed evenly, nor removed in the chosen area. Additionally, a substrate lying in a domed fashion would cause the problem that, possibly, too much, or too little substrate would be removed in direction Y.

When substrate 10 with one corner has arrived at nozzle 11, receiving element 2, along with substrate 10 is rotated and the process is repeated. These process steps are repeated as long as it takes for all chosen edges and/or sides of substrate 10 to have been processed.

During the process of emitting the solution medium from nozzle 11, the emitted solution medium, which bounces back from substrate 10, and/or the covering layer absolved from the substrate are suctioned. [Guckt euch noch mal den deutschen Satz an. Da ist der Wurm drin].

The liquid and/or particle-gas mixture, which has been suctioned off, arrives through a suctioning opening 14 in a canal 15. Via canal 15 the liquid and/or particle-gas mixture, which has been suctioned off, is lead into condensating chamber 17 and is brought to a sudden halt at bouncing wall 16. Due to this process, the liquid condensates at bouncing wall 16. Via discharge 19, the condensated solution medium is lead into a filter or recycling facility.

The gaseous components of the suctioned medium are suctioned, via open side 18 of condensating chamber 17, into chamber 20 and, via valve 21, are suctioned off by the source of pressurized air not illustrated herein.

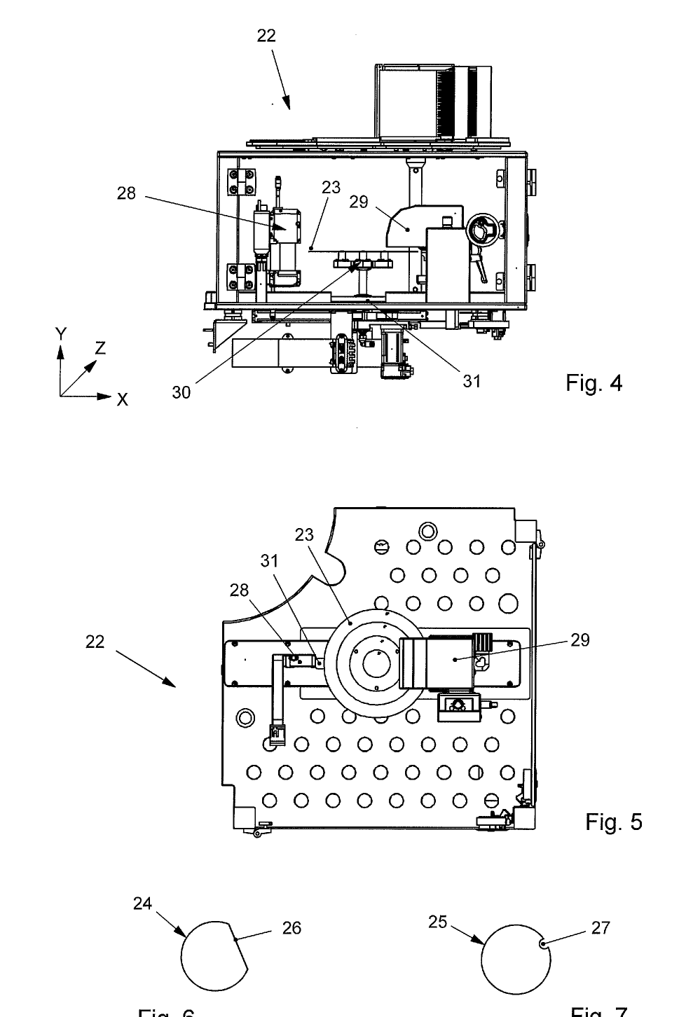

FIG. 4 shows a further embodiment of a device 22 intended for the removal of a covering layer from a substrate 24, 25, especially from a round substrate 24, 25.

FIGS. 6 and 7 show two different embodiments of a round substrate 24 and 25. Round substrate 24 possesses, as an uneven segment, a flat 26. Round substrate 25 forms by removing from a circular disc a circle arch segment.

Round substrate 25 possesses a notch 27. Notch 27 is constituted by a cut-out formed as a circle segment or a notch.

Device 22 comprises a recognizing facility 28. The latter comprises, preferably, a camera or a sensor, which is suited to recognizing the contour of a substrate.

Device 22 comprises a removal facility 29. Removal facility 29 is formed essentially in analogy to removal facility 3. In the embodiment presented herein removal facility 29 is designed to be stationary.

Preferably, removal facility 29 and recognition facility 28 are positioned at such a distance from each other that they do not simultaneously join with the substrate. Thus results the advantage that recognition facility 28 is polluted to the least possible extent.

Device 22 comprises as receiving element 30 with a receiving plate 23. Receiving element 30, respectively, receiving plate 23 is suited to the task of holding, turning and positioning one of substrates 24 or 25.

Receiving element 30 comprises a rotational power drive not illustrated herein. The later is suited to the task of rotating receiving element 30 and, consequently, also a substrate in a plane Z-X.

Device 22 comprises a linear guide 31. Linear guide 31 extends between recognition facility 28 and removal facility 29.

Device 22 comprises a linear force drive not illustrated herein. The linear force drive is suited the task of sliding receiving element 30, together with the rotational power drive, along linear guide 31 in direction X.

The device according to the embodiments of FIGS. 4 and 5 functions as follows:

Especially for the process of removing paint from a round substrate, for example substrate 24 or substrate 25, said substrate is laid upon holding plate 23 of receiving element 30.

Then receiving element 30 is slid along linear guide 31, by means of the linear force drive, in relation to recognition facility 28 in such a manner that with the recognition facility a contour of the substrate can be recognized.

When substrate 24, 25 is positioned, receiving element 30 and, consequently, also substrate 24, 25 is rotated to lie beneath recognition facility 28 in the plane X-Z. By these means, and aided by recognition element 28, a total circumference contour of substrate 24, 25 can be detected. The form and position of a flat 26 or a notch 27 are recognized. The form and the position of the uneven segment are recognized or detected.

Subsequently, receiving element 30, together with substrate 24, 25 are slid in direction X in relation to removal facility 29, in such a manner that the latter can remove a covering layer in a marginal area of substrate 24, 25. As long as the circular circumference of substrate 24, 25 is being dealt with, it is sufficient to rotate the receiving element only in the plane X-Z.

When the uneven contours 26 and 27 come into the area of nozzle 32, respectively, the jet of solution medium, receiving element 27, respectively, the substrate is moved in direction X in such a manner that, by overlaying linear movement and rotational movement, substrate 24, 25 is guided, along its contours 26 and 27, underneath nozzle 32. In this process, the covering layer is removed in an edge area along the entire contour.

1-14. (canceled)

15. A device for the removal of a covering layer from a substrate in at least an area of the substrate comprises a nozzle for applying a jet of a solution medium suitable for removing the covering layer.

16. A device according to claim 15, wherein the nozzle comprises a jet for applying the solution medium which is guided within the jet by pressurized air.

17. A device according to claim 15, further including a suctioning facility.

18. A device according to claim 17, wherein the suctioning facility comprises a condensator.

19. A device according to claim 17, wherein the suctioning facility comprises a bouncing wall for condensating the suctioned medium.

20. A device according to claim 15, further including a receiving element for holding and positioning the substrate.

21. A device according to claim 15, further including an adjusting unit for directionally adjusting the substrate in relation to the nozzle.

22. A device according to claim 15, further including a recognition facility for recognizing a contour of the substrate.

23. A device according to claim 15, further including a rotational power drive for rotating a receiving element.

24. A device according to claim 23, further including a linear drive for sliding the receiving element in relation to the nozzle.

25. A method for the removal of a covering layer from a substrate in at least an area of the substrate, comprising the following steps:
providing a substrate having a covering layer;
directionally adjusting the substrate; and
applying a jet of a solution medium to the covering layer of the substrate.

26. A method according to claim 25, further including the steps of:
stretching flat the substrate; and
positioning one of the substrate and the jet of solution medium on a chosen width of area where the covering layer is to be removed.

27. A method according to claim 26, further including:
guiding the jet of solution medium within a jet of pressurized air; and
performing a relational movement between the substrate and the jet of solution medium.

28. A method according to claim 27, further including:
recognizing a contour on the substrate;
positioning the substrate in relation to the jet of solution medium depending on a chosen width of the area in which the covering layer is to be removed; and
sliding the substrate by means of the receiving element depending on the recognized contour, in such a manner that a marginal area of the substrate is entirely freed of paint.
